(19) United States
(12) Patent Application Publication
(10) Pub. No.: US 2026/0300570 A1
(43) Pub. Date: Oct. 1, 2026

(54) TRAFFIC FLOW MODELING METHOD FOR GLOBAL ROUTE PLANNING

(71) Applicant: Jilin University, Changchun (CN)

(72) Inventors: Qifang Liu, Changchun (CN); Yunfeng Hu, Changchun (CN); Hong Chen, Changchun (CN); Dongzi Li, Changchun (CN); Hanyu Yang, Changchun (CN)

(21) Appl. No.: 19/097,768

(22) Filed: Apr. 1, 2025

(51) Int. Cl. G06F 30/18; G06F 30/15

(52) U.S. Cl. CPC G06F 30/18; G06F 30/15

(57) ABSTRACT

According to the present disclosure, a traffic flow modeling method for global route planning includes: using SUMO simulation software to establish a road network and a traffic flow model; establishing a SUMO/Matlab joint simulation platform; establishing a road network mathematical model; and generating reachable routes according to the road network mathematical model. The present disclosure builds more realistic road network scenarios and traffic flow scenarios and provides the road network mathematical model for global route planning, which provides a simple and efficient method for subsequent route generation.

### TECHNICAL FIELD

The present disclosure belongs to the technical field of traffic management, and more particularly to a traffic flow modeling method for global route planning.

### BACKGROUND

With the development of information technology such as communication, sensing, and computing and the continuous maturity of Internet of Vehicles technology, elements such as vehicles, sensors, pedestrians, and transportation facilities are gradually integrated into a whole. Through terminal control, interaction between individuals is achieved, thereby improving load capacity and traffic efficiency of a road network. Traffic simulation is the process of using modern computer technology to simulate real traffic systems and establish mathematical calculation models. It is an important technical approach for research in the field of transportation and the main means of current research on intelligent connected vehicle technology. According to the difference in model size, traffic simulation models mainly include macro models, micro models and meso models. Objects of the macro models are mainly integrated traffic variables, such as traffic flow, vehicle density, average speed, etc.; the micro models study traffic dynamics from the perspective of individual drivers. Driver behaviors include following other vehicles, changing lanes, and choosing routes. The movement of each vehicle in the simulation model generally assumes that the vehicle behavior depends on both the physical properties of the vehicle and the control behavior of the driver.

Carrying out Internet of Vehicles research and testing in real scenarios requires a lot of manpower, material resources and financial resources, and the safety of personnel cannot be guaranteed. Therefore, current research on the Internet of Vehicles technology is mostly carried out through computer software simulation technology. Existing simulation technologies have matured in the development of vehicle dynamics and kinematics modeling, but lack modeling methods for simulating real traffic flows. Existing traffic simulation models have certain limitations in obtaining road information in real time. Building of the mathematical model of the road network based on route planning cannot fully include individual information in the road network and the relationship between individuals. To this end, we propose a traffic flow modeling method for global route planning.

### SUMMARY

A purpose of the present disclosure is to provide a traffic flow modeling method for global route planning, aiming to solve the problems raised in the above-mentioned background technology.

To achieve the above purpose, the present disclosure provides the following technical solution:
a traffic flow modeling method for global route planning, including the following steps:
step S1: using SUMO simulation software to establish a road network and a traffic flow model: performing traffic flow generation, simulation parameter configuration and traffic flow model building, and then completing simulation output in the SUMO software by combining a traffic flow, simulation parameters and the road network;
step S2: establishing an SUMO/Matlab joint simulation platform: by the SUMO, communicating through a TraCI interface to realize joint simulation, wherein the TraCI interface adopts an Matlab language;
step S3: establishing a road network mathematical model; and
step S4: generating reachable routes according to the road network mathematical model.

Further, specific operations of step S1 are:
a. performing road network selection: selecting a road network area in an open source map, and exporting an editable road network document according to the road network area;
b. completing map editing: editing and repairing the editable road network document; and
c. performing setting of road network parameters: performing sequential numbering of road network elements.

Further, in step S2, the SUMO includes a controller; and the Matlab includes a traffic data acquisition module and an optimization scheme module.

Further, specific operations of step S2 are:
by the traffic data acquisition module in the Matlab, obtaining data of the road network elements from the traffic flow model through TraCI.get series functions and inputting the data into the optimization scheme module, and after obtaining an optimization result, by the controller, controlling the target vehicle through the TraCI.set series functions to form closed-loop control.

Further, specific operations of step S3 are:
assuming that N is a drivable branch of all target areas, a branch where a starting point is located is 1, and a branch where an end point is located is N; and defining a matrix G={gᵢⱼ}_{N×N} as a relationship between the branches;
where: a matrix element gᵢⱼ is a variable, which represents a passing ability from branch i to branch j: if branch i is connected to branch j, and a vehicle can travel directly from branch i to branch j, then gᵢⱼ is equal to a number of a traffic intersection pointed to by branch i, otherwise gᵢⱼ is equal to 0.

Further, specific operations of step S4 are:
recording a current position of the target vehicle as a₀, and a target position as a_{E};
recording a reachable route set as B, representing the reachable route using an array, recorded as A={a₀, a₁, . . . , a_{E}}, when the target vehicle is on a road a₀, extracting vertical coordinates of non-zero elements of the a₀-th row of the matrix G, recorded as Wₐ_{₀}=(w₁, w₂, . . . , wᵢ), that is, w₁, w₂, . . . , wᵢ is a set of passable branches of the road a₀;
if Wₐ_{₀} is an empty set, restarting a new cycle;
if Wₐ_{₀} is not an empty set, randomly selecting an element wᵢ in Wₐ_{₀}, if wᵢ has not appeared in A, selecting the element wᵢ as an element after do in set A, recorded as a₁; and if wᵢ has appeared in A, eliminating the element from Wₐ_{₀} and randomly selecting a next element; and
when the selected branch is a_{E} in the n-th cycle, that is, when aₙ is a_{E}, ending the cycle and outputting the reachable route A; recording B={A₁, A₂, . . . , Aₘ} as the reachable route set, and if there is no element in B that is the same as that in A, merging A into B.

Compared with prior art, the present disclosure has the following beneficial effects:

The present disclosure uses the simulation software to build more realistic road network scenarios and traffic flow scenarios, at the same time provides the road network mathematical model for global route planning, and builds the simulation platform through the TraCI communication interface, which not only constructs reasonable macro traffic information such as a traffic flow speed, but also can obtain real-time micro traffic information such as a vehicle speed, a position, and traffic lights, provides a simple and efficient method for subsequent route generation and is suitable for promotion.

### BRIEF DESCRIPTION OF THE DRAWINGS

FIG. 1 is a flow chart of the present disclosure.

FIG. 2 is a flow chart of traffic simulation in SUMO of the present disclosure.

FIG. 3 is a real road network in an open source map of the present disclosure.

FIG. 4 is a simple road network built in SUMO of the present disclosure.

FIG. 5 is a traffic flow generated with a frequency of 0.2 under a simple road network of the present disclosure.

FIG. 6 is a traffic flow generated with a frequency of 0.1 under a simple road network of the present disclosure.

FIG. 7 is a traffic flow generated with a frequency of 0.2 under a real road network of the present disclosure.

FIG. 8 is a traffic flow generated with a frequency of 0.1 under a real road network of the present disclosure.

FIG. 9 is a schematic diagram of joint simulation in the present disclosure.

FIG. 10 is a simplified model of a simple road network of the present disclosure.

FIG. 11 is a flow chart of reachable routes generated by the present disclosure.

### DETAILED DESCRIPTION

In order to make the purpose, technical solutions and advantages of the present disclosure more clearly understood, the present disclosure is further described in detail below in conjunction with the accompanying drawings and embodiments. It should be understood that the specific embodiments described herein are only used to explain the present disclosure, and are not used to limit the present disclosure.

The specific implementation of the present disclosure is described in detail below in conjunction with specific embodiments.

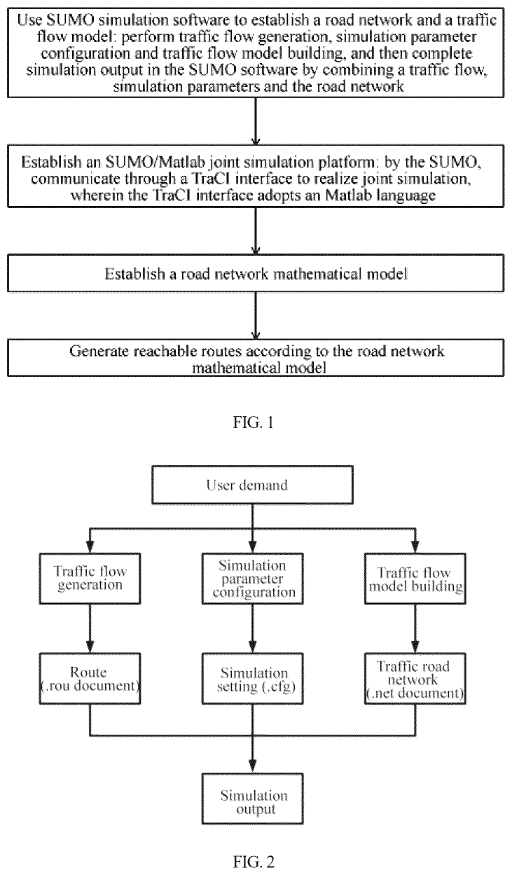

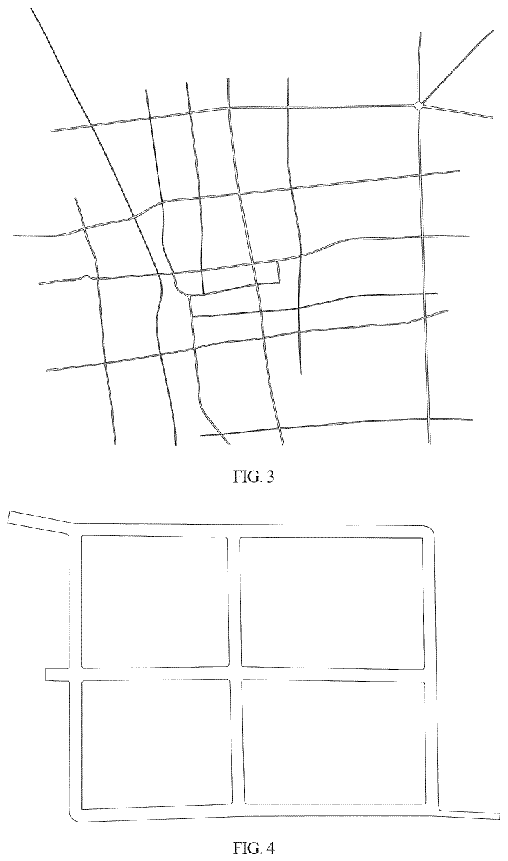

As shown in FIG. 1, a traffic flow modeling method for global route planning provided by an embodiment of the present disclosure includes the following steps:
step S1: using SUMO simulation software to establish a road network and a traffic flow model: performing traffic flow generation, simulation parameter configuration and traffic flow model building respectively as required, and then completing simulation output in the SUMO software by combining a traffic flow, simulation parameters and the road network (see FIG. 2);
step S2: establishing an SUMO/Matlab joint simulation platform: by the SUMO, communicating through a TraCI interface to realize joint simulation, wherein the TraCI interface adopts an Matlab language;
step S3: establishing a road network mathematical model; and
step S4: generating reachable routes according to the road network mathematical model.

As a preferred embodiment of the present disclosure, specific operations of step S1 are:
a. performing road network selection: selecting a road network area with many main roads, clear and crisscross layout, and reasonable traffic light density in an open source map, and extracting the area to export an editable road network document;
b. completing map editing: editing and repairing the editable road network document, such as size modification, road repair, deletion of irrelevant equipment, addition or removal of constraints, and removing pedestrian non-motorized vehicle lanes, and retaining the main roads accessible to motor vehicles, so that they can meet modeling requirements; and
c. performing setting of road network parameters: performing sequential numbering of road network elements such as roads, intersections, sensors and traffic lights.

In an embodiment of the present disclosure, it can be seen from FIG. 3 and FIG. 4 that the number of vehicles at the initial moment and the end moment is 0, and the vehicle flow in the road network is similar to a normal distribution. This distribution is used to simulate the traffic flow over a period of time in a real road network. Traffic flows are generated with a frequency of 0.2 within 0 to 100 seconds and a frequency of 0.1 within 0 to 100 seconds under the real road network in the open source map (as shown in FIG. 3) and a simple road network built in the SUMO (as shown in FIG. 4) respectively.

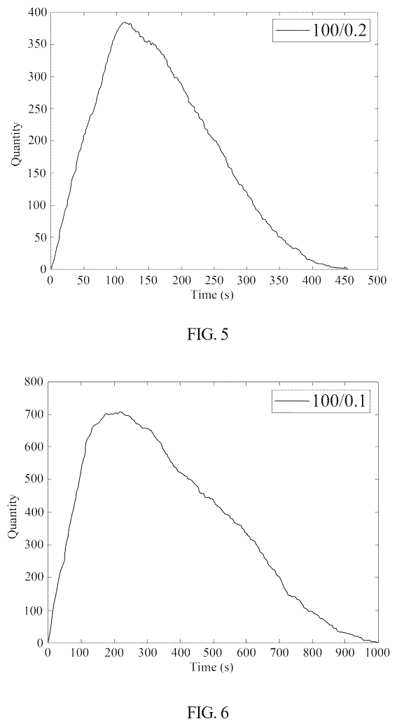

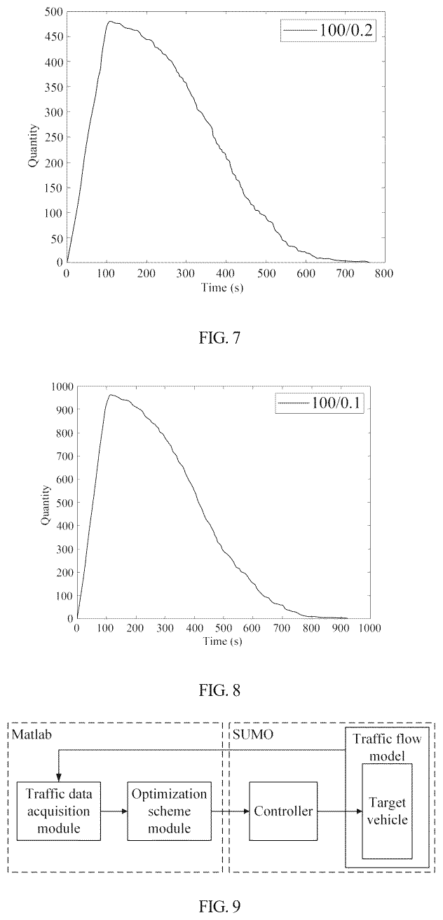

FIG. 5 shows a result of generating vehicles with a frequency of 0.2 (with 1 second as a vehicle generation cycle, 5 vehicles are generated per second) within 0 to 100 seconds under the simple road network. FIG. 6 shows a result of generating vehicles with a frequency of 0.1 (with 1 second as a vehicle generation cycle, 10 vehicles are generated per second) within 0 to 100 seconds under the simple road network. FIG. 7 shows a result of generating vehicles with a frequency of 0.2 (with 1 second as a vehicle generation cycle, 5 vehicles are generated per second) within 0 to 100 seconds under the real road network. FIG. 8 shows a result of generating vehicles with a frequency of 0.1 (with 1 second as a vehicle generation cycle, 10 vehicles are generated per second) within 0 to 100 seconds under the real road network.

By comparison, it can be seen that no matter in the real road network or the simple road network, the above method can simulate the traffic flow model of the total number of vehicles in the road network that changes over time and approximates the Poisson distribution, thereby simulating the total number of vehicles in the real traffic flow.

As a preferred embodiment of the present disclosure, in step S2, S the SUMO includes a controller; and the Matlab includes a traffic data acquisition module and an optimization scheme module; the optimization scheme module can generate several routes by applying reachable route generation rules according to the acquired real-time traffic information, current position information of the vehicle and a destination; and then, a global “optimal” driving route of the vehicle is solved according to a preset algorithm in the optimization scheme module.

Specific operations of step S2 are:

by the traffic data acquisition module in the Matlab, obtaining data of the road network elements such as roads, intersections, sensors, and traffic lights from the traffic flow model through TraCI.get series functions and inputting the data into the optimization scheme module, and after obtaining an optimization result, by the controller, controlling the target vehicle through the TraCI.set series functions to form closed-loop control (see FIG. 9).

In an embodiment of the present disclosure, the SUMO as traffic simulation software can realize the simulation of many real traffic scenario. When the SUMO is used as a test platform for intelligent traffic control algorithms, there is a need for two-way communication with an optimization scheme. The user-defined optimization scheme can obtain real-time traffic information from the SUMO and then perform real-time control on variables such as a vehicle speed. The TraCI interface can be used to obtain data from the SUMO traffic simulation environment and perform real-time modification and control. Currently, the interface supports a variety of mainstream languages, including python, C++, .NET, MATLAB and Java. In the present disclosure, the Matlab language is selected, and the TraCI4Matlab functions used are shown in Table 1.

TABLE 1
TraCI4Matlab Function Performance

| TraCI4Matlab Function | Function Performance |
|---|---|
| traci.vehicle.getPosition(vehID) | Getting a current position of the vehicle (vehID) |
| traci.vehicle.getRoute(vehID) | Getting a current road of the vehicle (vehID) |
| traci.vehicle.setRoute(vehID) | Setting a route of the vehicle (vehID) |
| traci.lane.getLength(lanelD) | Getting the length of a current lane (laneID) |

As a preferred embodiment of the present disclosure, in step S2, the present disclosure realizes two-way communication by combining SUMO and TraCI, and obtains a large amount of data from the traffic flow model through the TraCI.get series functions, but it is difficult to efficiently process the data obtained by TraCI to obtain a description of the relationship between roads in the entire road network. In order to quickly generate multiple reachable routes and realize an intuitive description of the road network relationship in Matlab, the present disclosure establishes a road network mathematical model, which is expressed through a two-dimensional matrix.

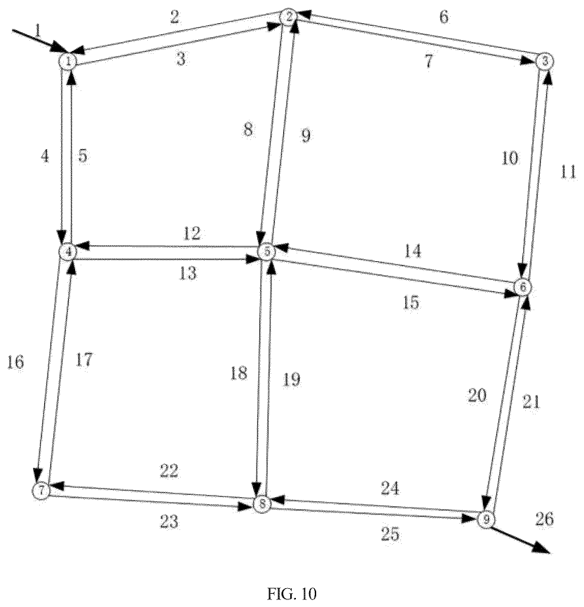

Similar to other route planning studies, a traffic network can be simplified into nodes and branches. Nodes represent crossroads or forks, and branches represent passable sections of road between nodes. Taking the simple road network in FIG. 10 as an example, the figure represents a simplified node-branch model, the arrows indicate the direction of vehicle travel, the numbers correspond to numbers, and \textcircled{1}~\textcircled{9} represent intersections 1 to 9. The starting and ending points are the diagonal roads “1-26” respectively, and the target area is determined. Specific steps are: assuming that N is a drivable branch of all target areas, a branch where a starting point is located is 1, and a branch where an end point is located is N; and defining a matrix G={gᵢⱼ}_{N×N} as a relationship between the branches; where: a matrix element gᵢⱼ is a variable, which represents a passing ability from branch i to branch j: if branch i is connected to branch j, and a vehicle can travel directly from branch i to branch j, then gᵢⱼ is equal to a number of a traffic intersection pointed to by branch i, otherwise gᵢⱼ is equal to 0.

In an embodiment of the present disclosure, taking the branch 13 in FIG. 10 as an example, the branch 13 enables going straight, turning right, turning left, or turning around, that is, the road 13 is connected to the branch 12, the branch 15, the branch 9, and the branch 18 through the intersection No. 5. Hence, the 13th row of G in FIG. 10 is [0 0 0 0 0 0 0 0 5 0 0 5 0 0 5 0 0 5 0 0 0 0 0 0 0 0], with a total of 26 dimensions, of which the 9th, 12th, 15th and 18th elements are equal to 5, and the rest are equal to 0.

As a preferred embodiment of the present disclosure, specific operations of step S4 are:

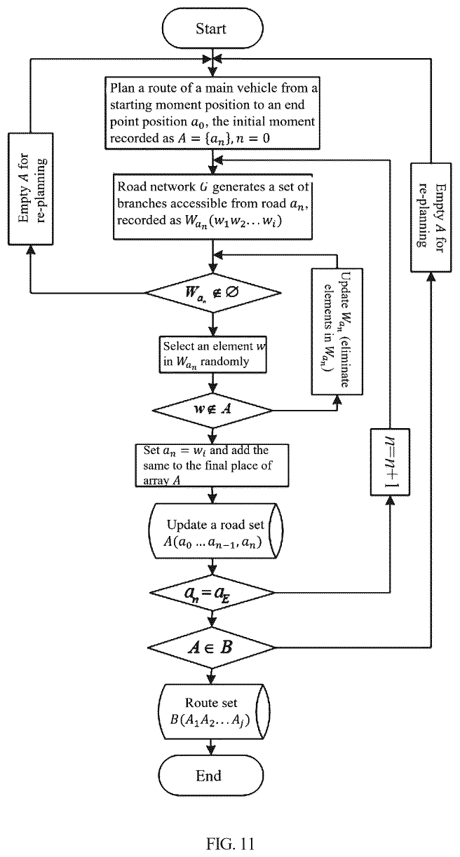

According to the above road network mathematical model and “starting point-end point”, recording a current position of the target vehicle as a₀, and a target position as a_{E}. The road network matrix G describes the connection relationship between branches. In order to ensure the rationality of generating reachable routes, “each road is passed at most once” is set as a constraint, as shown in FIG. 11. The specific process is as follows:

recording a reachable route set as B, representing the reachable route using an array, recorded as A={a₀, a₁, . . . , a_{E}}, when the target vehicle is on a road a₀, extracting vertical coordinates of non-zero elements of the a₀-th row of the matrix G, recorded as Wₐ_{₀}=(w₁, w₂, . . . , wᵢ), that is, w₁, w₂, . . . , wᵢ is a set of passable branches of the road a₀;
if Wₐ_{₀} is an empty set, restarting a new cycle;
if Wₐ_{₀} is not an empty set, randomly selecting an element wᵢ in Wₐ_{₀}, if wᵢ has not appeared in A, selecting the element wᵢ as an element after do in set A, recorded as a₁; and if wᵢ has appeared in A, eliminating the element from Wₐ_{₀} and randomly selecting a next element; and
when the selected branch is a_{E} in the n-th cycle, that is, when aₙ is a_{E}, ending the cycle and outputting the reachable route A; recording B={A₁, A₂, . . . , Aₘ} as the reachable route set, and if there is no element in B that is the same as that in A, merging A into B. According to the above method, several reachable routes can be obtained when the “starting point-end point” is known.

The above are only preferred embodiments of the present disclosure. It should be noted that, for those skilled in the art, without departing from the inventive concept, some modifications and improvements can also be made, which should also be regarded as the protection scope of the present disclosure, and these will not affect the effect of the implementation of the present disclosure and the practicality of the patent.

1. A traffic flow modeling method for global route planning, comprising the following steps:
step S1: using SUMO simulation software to establish a road network and a traffic flow model: performing traffic flow generation, simulation parameter configuration and traffic flow model building, and then completing simulation output in the SUMO software by combining a traffic flow, simulation parameters and the road network;
step S2: establishing an SUMO/Matlab joint simulation platform: by the SUMO, communicating through a TraCI interface to realize joint simulation, wherein the TraCI interface adopts an Matlab language;
step S3: establishing a road network mathematical model; and
step S4: generating reachable routes according to the road network mathematical model:
specific operations of step S3 are:
assuming that N is a drivable branch of all target areas, a branch where a starting point is located is 1, and a branch where an end point is located is N; and defining a matrix G={gᵢⱼ}_{N×N} as a relationship between the branches;
where: a matrix element gᵢⱼ is a variable, which represents a passing ability from branch i to branch j: if branch i is connected to branch j, and a vehicle can travel directly from branch i to branch j, then gᵢⱼ is equal to a number of a traffic intersection pointed to by branch i, otherwise gᵢⱼ is equal to 0;
specific operations of step S4 are:
recording a current position of the target vehicle as a₀, and a target position as a_{E};
recording a reachable route set as B, representing the reachable route using an array, recorded as A={a₀, a₁, . . . , a_{E}}, when the target vehicle is on a road a₀, extracting vertical coordinates of non-zero elements of the a₀-th row of the matrix G, recorded as Wₐ_{₀}=(w₁, w₂, . . . , wᵢ), that is, w₁, w₂, . . . , wᵢ is a set of passable branches of the road a₀;
if Wₐ_{₀} is an empty set, restarting a new cycle;
if Wₐ_{₀} is not an empty set, randomly selecting an element wᵢ in Wₐ_{₀}, if wᵢ has not appeared in A, selecting the element wᵢ as an element after do in set A, recorded as a₁; and if wᵢ has appeared in A, eliminating the element from Wₐ_{₀} and randomly selecting a next element; and
when the selected branch is a_{E} in the n-th cycle, that is, when aₙ is a_{E}, ending the cycle and outputting the reachable route A; recording B={A₁, A₂, . . . , Aₘ} as the reachable route set, and if there is no element in B that is the same as that in A, merging A into B.

2. The traffic flow modeling method for global route planning according to claim 1, wherein specific operations of step S1 are:
a. performing road network selection: selecting a road network area in an open source map, and exporting an editable road network document according to the road network area;
b. completing map editing: editing and repairing the editable road network document; and
c. performing setting of road network parameters: performing sequential numbering of road network elements.

3. The traffic flow modeling method for global route planning according to claim 2, wherein in step S2, the SUMO includes a controller; and the Matlab includes a traffic data acquisition module and an optimization scheme module.

4. The traffic flow modeling method for global route planning according to claim 3, wherein specific operations of step S2 are:
by the traffic data acquisition module in the Matlab, obtaining data of the road network elements from the traffic flow model through TraCI.get series functions and inputting the data into the optimization scheme module, and after obtaining an optimization result, by the controller, controlling the target vehicle through the TraCI.set series functions to form closed-loop control.

5. The traffic flow modeling method for global route planning according to claim 1, wherein in step S4, the reachable routes are constrained: each road may be passed at most once.
